(19) United States
(12) Patent Application Publication
(10) Pub. No.: US 2025/0038004 A1
(43) Pub. Date: Jan. 30, 2025

(54) CONDUCTIVE MATERIAL DEPOSITION ON SEMICONDUCTOR WITH PHASE TRANSITION AND OHMIC CONTACT IN SITU

(71) Applicant: The Hong Kong University of Science and Technology, Hong Kong (CN)

(72) Inventors: Sen YANG, Hong Kong (CN); Zeying CHEN, Hong Kong (CN); Wing Ki LO, Hong Kong (CN); Ning WANG, Hong Kong (CN)

(21) Appl. No.: 18/782,040

(22) Filed: Jul. 24, 2024

Related U.S. Application Data
(60) Provisional application No. 63/515,594, filed on Jul. 26, 2023.
(60) Provisional application No. 63/518,880, filed on Aug. 11, 2023.

(51) Int. Cl. H01L 21/288; H01L 29/16; H01L 29/24; H01L 29/45; H01L 29/772

(52) U.S. Cl. CPC H01L 21/288; H01L 29/45; H01L 29/1602; H01L 29/1606; H01L 29/1608; H01L 29/24; H01L 29/772

(57) ABSTRACT

A method for a photon induced conductive material deposition on a substrate is provided. The method includes steps as follows: preparing a first solution comprising metalate, metal ions, or combinations thereof; preparing a first suspension comprising nanoparticles, a light sensitive reducing agent, an electron providing solvent, or combinations thereof; mixing the first solution and the first suspension to form a first reagent on a first substrate; and emitting a light beam provided by a light source and focusing the same onto the first reagent kept on a first region of the first substrate, so as to form a mechanically rigid conductive deposition in contact with the first substrate in a focus point of the light source, wherein the first substrate has a second region exposed to surrounding gas or an air environment.

### CROSS-REFERENCE TO RELATED APPLICATIONS

The present application claims priority from the U.S. provisional patent application Ser. No. 63/515,594 filed 26 Jul. 2023 and the U.S. provisional patent application Ser. No. 63/518,880 filed 11 Aug. 2023, and the disclosures of which are incorporated herein by reference in their entirety.

### TECHNICAL FIELD

The present invention generally relates to techniques for a semiconductor structure and a manufacturing method thereof. More specifically, the present invention relates to a semiconductor structure and a manufacturing method thereof, using conductive material deposition on semiconductor with phase transition and ohmic contact in situ.

### BACKGROUND

The microelectronics and display industries rely on the pattern formation of conductive materials on semiconductor to establish micro circuits on flexible and hard substrates. The primary methods for generating these patterns are thin film and etching methods for features smaller than about 100 μm. For lower resolution application, Fused deposition modeling (FDM), polyJet printing, direct ink writing (DIW), stercolithography (SLA)/digital light processing (DLP), selective laser sintering (SLS), and direct laser writing (DLW) are most commonly used methods.

Although few methods show the possibility on precision deposition technique, they are either too complicated in process which require plenty of time, or they cost too much. More important they usually also put extra requirements in the design, sample, working space and manpower. DLW provides possible solution for overcome the mentioned problems.

As the downscaling of devices approaches its limit, innovative materials to Si are under exploration to maintain extension of Moore's law scaling. Recently introduced 2D materials, especially semiconducting transition metal dichalcogenides (TMDs), such as molybdenum disulfide (MoS₂), tungsten diselenide (WSe₂) and Molybdenum Ditelluride (MoTe₂), with atomic scale thickness, have emerged as game changer in the current MOSFET downscaling technology. As the channel material of field-effect transistors (FET), TMDs offer dangling-bond free surface, high thermal stability and significant tunable bandgap, which show the immunity to short channel effect and turn out to be the strong candidates to next revolution of the mainstream IC manufacturing.

On the other hand, with ultra-thin structure and delicate lattice, obtaining high quality metal-semiconductor (M-S) contact on 2D materials remains a critical challenge. The contact governs the charge carrier injection from metal to 2D channel. A large Schottky barrier can significantly deteriorate the performance of a FET, such as current on/off ratio, field-effect mobility, and the drain current. Without ohmic contact, the response would be delayed due to the tunneling in the high-speed circuit. However, with many strict conditions, such as a neat contact between metal and 2D material and Fermi level pinning effect, there are difficulties on pursuing pure non-rectifying Ohmic contacts. This research direction has ushered in a boom after the rapid development of 2D materials. Several attempts have been made to vanish the large potential barrier height: metal with low work function, ultrahigh vacuum evaporation, doping, edge contact and more. Although these efforts have reduced the contact resistance to acceptable levels, like hundreds of Ohms per micrometer, they are still way above the ideal resistance of ohmic contact; and, without exception, they all require complex processes or harsh environmental conditions, or could not be adapted to small scale to smaller than 100 μm. More important, they usually put extra requirements in the sample and functional temperature, cause destruction or total property change on materials, or require metals with high resistivity.

One of the key challenges is to find a mechanism that can realize ohmic contact on 2D material. The mechanism has to be general enough that it can be applied to commonly used metal and 2D materials on many types of substrates. In modern silicon-based device application, metal electrodes were fabricated onto the degenerate doped n++ or p++ regions to manipulate source and drain contact and channel type. A higher conductive state of channel material helps with the limitation the mismatch of Fermi level at the interface, the injection of charge carriers and the reduction of contact resistance. Similar strategy could be applied in 2D material, while doping is challenging due to the nature of atomically thin and faced with the problem of instability.

A common method for the realization of ohmic contact on M-S interface is to form phase transition on semiconductor. This direction including stress application, plasmonic electron doping, chemical reaction, argon plasma and alkali ion doping. Most of these methods face the inability to locally form phase transition to maintain the original property of the channel. Besides, these methods usually require nontrivial environment such as alkali or high pressure. These problems limit the application of phase transition method on achieving ohmic contact.

Therefore, there is a need for an improved approach of conductive material deposition on a surface of a semiconductor substrate with ohmic contact by phase transition in situ, so as to conquer the above problems and allow direct testing of for semiconductor samples easily.

### SUMMARY OF INVENTION

It is an objective of the present invention to provide semiconductor structures and methods for the same to address the aforementioned issues in the prior arts.

In the present invention, the solution relates to material deposition that is useful for the production of electrically conductive features and patterns. An important feature is that direct laser writing deposits conductive material and forms ohmic contact on semiconductor in situ simultaneously by phase transition. The composition for the ohmic contact may advantageously be deposited on a variety of semiconductors at low temperatures, allowing direct testing on mono-layer, bi-layer, or multi-layer semiconductors, and also manufacturing diodes, transistors, and microcircuits with different functions.

In accordance with one aspect of the present invention, a method for a photon induced conductive material deposition on a substrate is provided. The method includes steps as follows: preparing a first solution comprising metalate, metal ions, or combinations thereof; preparing a first suspension comprising nanoparticles, a light sensitive reducing agent, an electron providing solvent, or combinations thereof; mixing the first solution and the first suspension to form a first reagent on a first substrate; and emitting a light beam provided by a light source and focusing the same onto the first reagent kept on a first region of the first substrate, so as to form a mechanically rigid conductive deposition in contact with the first substrate in a focus point of the light source, wherein the first substrate has a second region exposed to surrounding gas or an air environment.

In accordance with one aspect of the present invention, a semiconductor device using a photon induced conductive material deposition is provided. The semiconductor device includes a first substrate, a mechanically rigid conductive deposition, a second substrate. The first substrate has a first region and a second region adjacent to the first region, in which the first substrate comprises MoS₂, MoSe₂, MoTe₂, WSe₂, graphene, a layer with metallic isomers, or combinations thereof, serving as two-dimensional materials to form at least one channel within the first substrate. The mechanically rigid conductive deposition is formed as a conductive pattern disposed above the first region of the first substrate, in which the mechanically rigid conductive deposition forms an ohmic contact with the first region of the first substrate and is a solid and rigid composite pattern made of pure metal, solid metal salt, metal oxide, or combinations thereof. The second substrate is attached to the first substrate, in which the mechanically rigid conductive deposition is above the first substrate and the second substrate and extends from the first region of the first substrate to the second substrate.

In the present disclosure, the provided is a conductive material deposition for the fabrication of functional patterns with special electrical properties. The material deposition forms ohmic contact at the metal-semiconductor interface by semiconductor phase transition in situ. The material deposition forms a strong attachment to the substrate, permitting advantageous direct-write laser use. The material deposition also has a low conversion temperature, preventing damage to the material. The nanoparticle composition allows deposition without a mask on different substrates. The contact resistance between deposited metal and semiconductor is remarkably low, allowing direct measurement of semiconductor electrical properties without contact interference and Schottky barrier.

### BRIEF DESCRIPTION OF DRAWINGS

Embodiments of the invention are described in more details hereinafter with reference to the drawings, in which:

FIG. 1A is a top view of a semiconductor device according to some embodiments of the present disclosure;

FIG. 1B is a vertical cross-sectional view across a line I-I′ in FIG. 1A;

FIG. 1C is a vertical cross-sectional view across a line II-II′ in FIG. 1A;

FIG. 1D is a vertical cross-sectional view showing a profile of the local structure of the first substrate according to some embodiments of the present invention;

FIG. 2A, FIG. 2B, and FIG. 2C show schematic drawings illustrating a method for photon-induced deposition of conductive material to create electrodes on a semiconductor, thereby establishing ohmic contacts, according to some embodiments of the present disclosure;

FIG. 2D shows a further stage for obtaining one or more electrodes with the desired shape according to some embodiments of the present disclosure;

FIG. 3A, FIG. 3B, FIG. 3C, and FIG. 3D demonstrate Raman spectrum analysis of different precious metal deposition on different TMDs according to some embodiments of the present invention;

FIG. 4A, FIG. 4B, FIG. 4C, FIG. 4D collectively provide electrical measurement of a FET device manufactured using the solution according to some embodiments of the present invention;

FIG. 5 is a vertical cross-sectional view of a semiconductor device according to some embodiments of the present disclosure;

FIG. 6 is a vertical cross-sectional view of a semiconductor device according to some embodiments of the present disclosure;

FIG. 7 is a vertical cross-sectional view of a semiconductor device according to some embodiments of the present disclosure;

FIG. 8 is a vertical cross-sectional view of a semiconductor device according to some embodiments of the present disclosure;

FIG. 9 is a vertical cross-sectional view of a semiconductor device according to some embodiments of the present disclosure;

FIG. 10 is a vertical cross-sectional view of a semiconductor device according to some embodiments of the present disclosure;

FIG. 11 is a vertical cross-sectional view of a semiconductor device according to some embodiments of the present disclosure;

FIG. 12 is a vertical cross-sectional view of a semiconductor device according to some embodiments of the present disclosure;

FIG. 13 is a vertical cross-sectional view of a semiconductor device according to some embodiments of the present disclosure; and

FIG. 14 is a vertical cross-sectional view of a semiconductor device according to some embodiments of the present disclosure.

### DETAILED DESCRIPTION OF THE INVENTION

In the following description, semiconductor structures and methods using conductive material deposition on semiconductor with phase transition and ohmic contact in situ and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

In the present disclosure, various embodiments or examples illustrating different aspects of the subject matter are provided. It includes specific examples of components and arrangements. However, these descriptions are only illustrative and not meant to be restrictive. When describing features, mentioning that the first feature is formed on or above the second feature may refer to cases where the first feature directly contacts the second feature or where an additional feature separates them. Furthermore, reference numbers or letters may be repeated in examples for clarity and simplification, without implying a relationship between the different embodiments or configurations described.

In this context, to simplify explanations, terms related to spatial orientation such as “under”, “below”, “lower”, “above”, “upper”, “lower portion”, “left side”, “right side”, and similar expressions may be employed to illustrate the relationship between one component or feature and another component or feature depicted in the figures. Beyond the orientations depicted in the figures, these spatial terms are intended to encompass various orientations of the device during its use or operation. The device could be positioned differently (e.g., rotating the passivation layer by 90 degrees or in other orientations), and the spatial descriptors mentioned here may accordingly be applied for clarification. It's important to note that when a component is described as “connected” or “coupled” to another component, it could be directly connected to or coupled to that component, or there might be an intermediary component involved.

In the present disclosure, terms like “approximately”, “basically”, “substantially”, and “about” are used to describe slight variations. When combined with an event or circumstance, these terms may indicate both exact and approximate occurrences of the event or circumstance. When used concerning a specific value or range, “about” generally denotes within ±10%, ±5%, or ±1% of the given value or range. Unless stated otherwise, all ranges mentioned include their endpoints. For instance, “substantially coplanar” may denote surfaces positioned within a few micrometers (μm) of each other along the same plane, such as within 10 μm, 5 μm, or 1 μm.

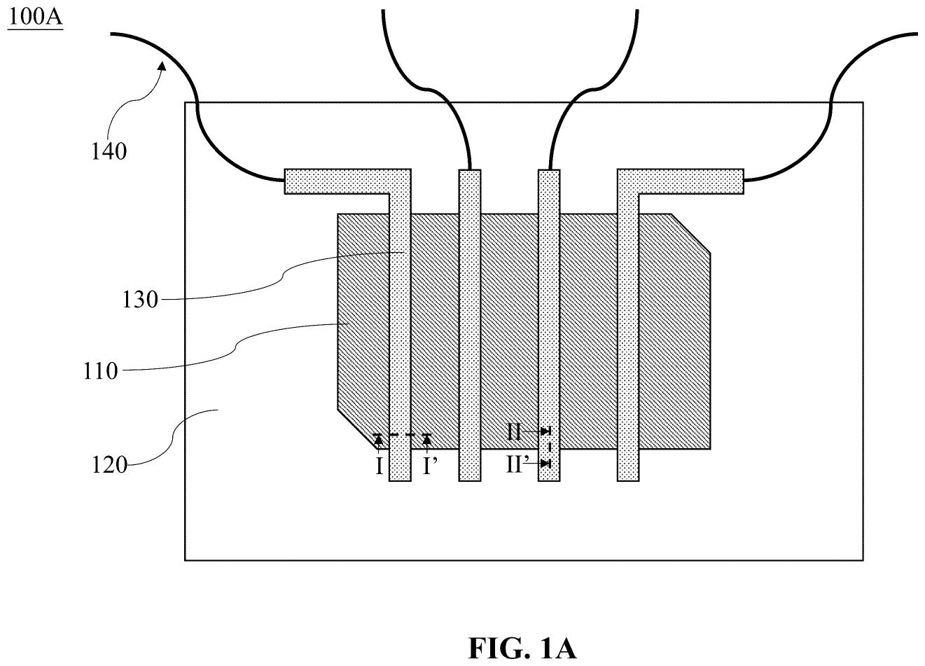

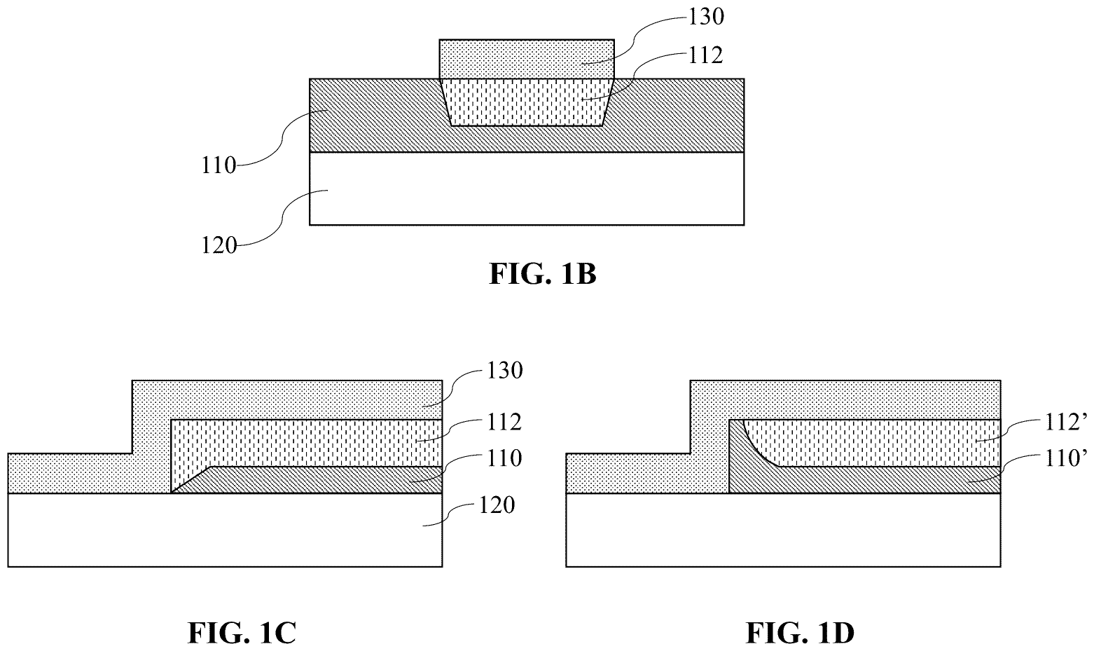

FIG. 1A is a top view of a semiconductor device 100A according to some embodiments of the present disclosure; FIG. 1B is a vertical cross-sectional view across a line I-I′ in FIG. 1A; and FIG. 1C is a vertical cross-sectional view across a line II-II' in FIG. 1A. The semiconductor device 100A includes a first substrate 110, a second substrate 120, and one or more electrodes established by a mechanically rigid conductive deposition 130.

In one embodiment, the first substrate 110 includes semiconducting transition metal dichalcogenides (TMDs) materials, such as MoS₂, MoSe₂, MoTe₂, WSe₂, graphene, a layer with metallic isomers, or combinations thereof. The TMD materials of the first substrate 110 are two-dimensional materials used to form channels for field-effect transistors (FETs) within the first substrate 110. The first substrate 110 is disposed over the second substrate 120. The first substrate 110 is connected to the second substrate 120; for example, the first substrate 110 is formed or grown from the second substrate 120, and thus the second substrate 120 is attached to the first substrate 110. In one embodiment, the second substrate 120 includes glass, quartz, sapphire, indium tin oxide, diamond, Si, SiC, oxidized silicon, combinations thereof. The first substrate 110 and the second substrate 120 are not limited to the afore-mentioned materials. In other embodiments, the first substrate 110 or the second substrate 120 may include one or more other features, such as a doped region, a buried layer, an epitaxial (epi) layer, or combinations thereof.

The mechanically rigid conductive deposition 130 is formed as a conductive pattern (e.g., one or more electrodes) disposed above a first region of the first substrate 110. In this regard, the first substrate 110 includes a first region covered by the one or more electrodes and a second region that is adjacent to the first region and is free from the coverage of the one or more electrodes. The mechanically rigid conductive deposition 130 is disposed above the first substrate 110 and the second substrate 120 and extends from the first region of the first substrate 110 to the second substrate 120.

The mechanically rigid conductive deposition 130 can form an ohmic contact with the first region of the first substrate 110. In one embodiment, the mechanically rigid conductive deposition 130 is a solid and rigid composite pattern made of pure metal, solid metal salt, metal oxide, or combinations thereof. For example, the mechanically rigid conductive deposition 130 includes Pt, Au, Ag, or combinations thereof, and/or their composition with C. Specifically, as the first substrate 110 is a semiconductor, at an interface between the first substrate 110 and the mechanically rigid conductive deposition 130, the local structure 112 of the first substrate 110 beneath the mechanically rigid conductive deposition 130 is transformed to metallic phase, which allows ohmic contact. In various embodiments, the local structure 112 of the first substrate 110 is a phase transition layer. It should be noted that the local structure 112 for the phase transition layer depicted in the drawings of the present disclosure is illustrative. In practice, its shape or dimensions are not required to scale as shown in the illustration of the drawings; for example, the phase transition layer 112 may be relatively thin relative to other layers. Furthermore, in some embodiments, the local structure 112 of the first substrate 110 have various profiles; for example, FIG. 1D is a vertical cross-sectional view showing a profile of the local structure 112′ of the first substrate 110′ according to some embodiments of the present invention, in which the local structure 112′ for the phase transition layer is separated from a sidewall/side edge of the first substrate 110′. That is, the profile of the local structure 112′ is not limited by the present disclosure.

This configuration can be achieved by a material deposition process using direct-write laser techniques at a low conversion temperature without a need for a mask on the first substrate 110 or the second substrate 120. In the present disclosure, as mentioned “low conversion temperature” means, during the material deposition process, the fabrication temperature, is room temperature or near room temperature. In some cases, the “low temperature” refers to a low testing temperature, allowing really low temperature far below zero degree Celsius, e.g., down to 100K or less than it.

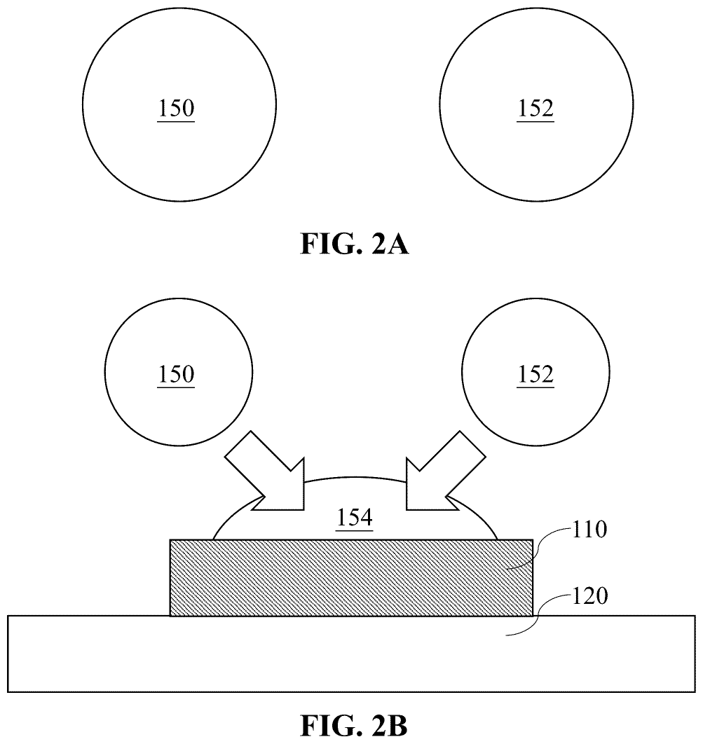

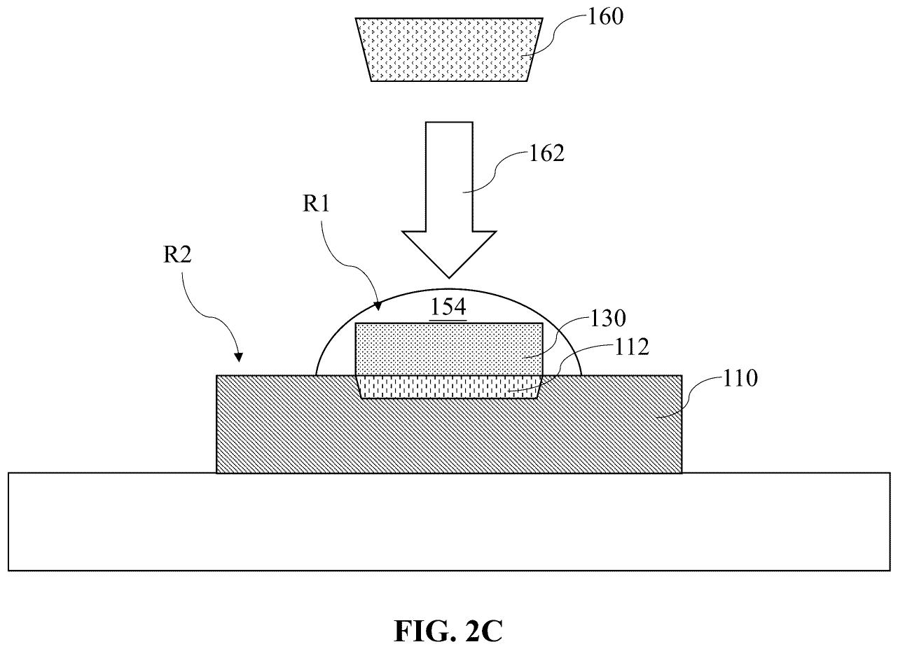

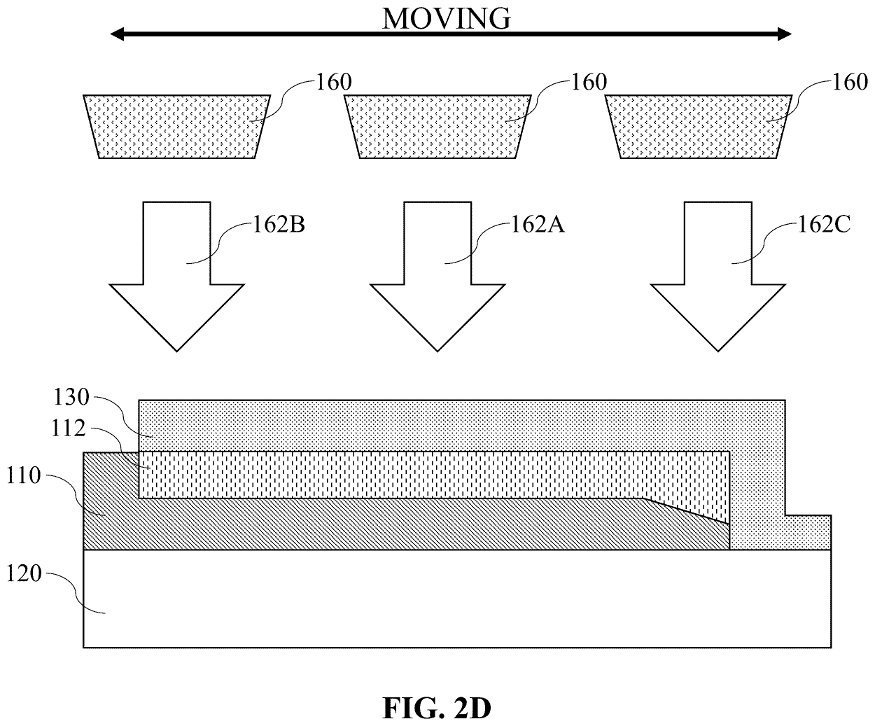

Specifically, FIG. 2A, FIG. 2B, and FIG. 2C show schematic drawings illustrating a method for photon-induced deposition of conductive material to create electrodes on a semiconductor, thereby establishing ohmic contacts.

In FIG. 2A, a first solution 150 and a first suspension 152 are prepared. The first solution 150 includes metalate, metal ions, or combinations thereof. In one embodiment, the first solution 150 includes gold (III) chloride hydrochloride (HAuCl₄), chloroplatinic acid (H₂PtCl₆), silver nitrate (AgNO₃), or combinations thereof. The first suspension 152 includes nanoparticles, a light sensitive reducing agent, an electron providing solvent, or combinations thereof. In one embodiment, the electron providing solvent includes water, ethanol, propanol, isopropanol, acetone, methanol, or combinations thereof. In one embodiment, the light sensitive reducing agent includes reduced graphene oxide, quantum dots, carbon ink particles, or combinations thereof.

In FIG. 2B, this stage starts with the transfer of the first substrate 110 (e.g., a semiconductor) on the second substrate 120 (e.g., a support base/substrate). Then, the first solution 150 and the first suspension 152 are mixed to form a first reagent 154 on the first substrate 110, so the prepared solution containing metalate or metal ions, reactive reductive ion, and low surface tension solvent is applied onto the surface of the first substrate 110. In one embodiment, the first reagent 154 is applied to the first substrate 110 by drop-casting, by spin-coating, by spraying, by microfluidic channels, by ink injections, or by combinations thereof.

In FIG. 2C, a light source 160 (e.g., a laser light source) provides a light beam 162 (e.g., a laser light beam) and emits the same toward the first substrate 110. The light beam 162 is focused same onto the first reagent (see FIG. 2B) kept on a first region R1 of the first substrate 110, so as to form a mechanically rigid conductive deposition 130 in contact with the first substrate 110 in a focus point of the light source 160, resulting in creating phase transition (i.e., the local structure 112 in FIG. 1B and FIG. 1C) at a semiconductor surface of the first region R1 of the first substrate 110 locally. In this regard, the first substrate has a second region R2 adjacent to the first region RI and exposed to surrounding gas or an air environment. That is, the process in the stage of FIG. 2C is a mask-free process during the formation of the mechanically rigid conductive deposition 130. Since the second region R2 is free from the irradiation of the light beam 162, this region within the second region R2 is free from any optical damage as well. Correspondingly, the creating the phase transition is achieved without changing at least one property of the semiconductor in the second region R2 of the first substrate 110. In the stage of FIG. 2C, the local structure 112 for the phase transition layer is formed as well; it should be noted that the dimension/profile/shape of local structure 112 for the phase transition layer depicted in FIG. 2C is illustrative.

Briefly regarding the interaction during the process, as the laser beam 162 with appropriate power is focused onto the semiconductor of the first substrate 110, the photon-induced chemical reduction process completes, causing the conductive material to aggregate into the mechanically rigid conductive deposition 130. In the meanwhile, material phase switching is triggered, from semi-conductive state into metallic state locally in situ, under the deposited material. Without mismatch of the work function between metal and semiconductor (the mechanically rigid conductive deposition 130 and the first substrate 110), ohmic contacts are successfully established (i.e., the mechanically rigid conductive deposition 130 forms an ohmic contact with the first region R1 of the first substrate 110 in situ). In one embodiment, the ohmic contact is accomplished by the co-existence of semiconductor phase transition to metallic state in situ and conductive material deposition by photon. As such, the process can deposit solid metallic structure with functional patterns and remain strong adhesion to the first substrate 110, allowing direct testing of semiconductor and device fabrication. For example, the testing can be taken by using testing wired routes 140 connected to the mechanically rigid conductive deposition 130 in FIG. 1A.

In this stage, although reduction happens, the first substrate 110 and the mechanically rigid conductive deposition 130 are still immersed in the first reagent 154. In some embodiments, the first reagent 154 is removed in a cleaning process. In various embodiments, when the liquid drop of the first reagent 154 is small enough, the mechanically rigid conductive deposition 130 may not be immersed (i.e., at least exposed from of the first reagent 154). In one embodiment, an entirety of the structure including substrate in combination of the first substrate 110 and the mechanically rigid conductive deposition 130 is in entire immersion.

The following provides further details on the reactions during the stage of FIG. 2C.

As afore-mentioned, the photon-induced chemical reduction process is completed, so the conductive material congregates into a mechanically rigid deposition; when the light beam 162 is focused on the first reagent, free electrons, excited from the valence band of the light-sensitive reducing agent, such as semiconductor nanoparticles, by photons, trigger a chemical reduction process. This process converts metal ions in the solution to metal particles on the surface of the semiconductor of the first substrate 110.

Then, as the very first bit of material takes shape, local laser heating increases vapor pressure until a vapor microbubble is formed. Convective flows and capillary forces carry particles towards the base of the microbubble where some of them are pinned. Simultaneously, the focused of the first substrate 110 also serves as an optical trap, driving particles towards the focal spot on the substrate surface of the first substrate 110, while the scattering force reinforces the adhesion between particles and the first substrate 110. Together with the photoelectrons generated by the semiconductor of the first substrate 110, the redox reaction is enhanced. Through the combination of these mechanisms, the reduced metal or metal oxide growing on the surface of the particles acts like a glue, bonding trapped particles together to form a mechanically rigid deposition (i.e., the mechanically rigid conductive deposition 130) on the substrate surface of the first substrate 110 or on a layer of already deposited material (for 3D patterns).

At the same time, strong adhesion is provided between the deposited material and the first substrate 110 by an etching mechanism in situ. Simultaneously, semiconductor phase transition occurs in situ through electron transfer or local electric fields. The electron transfer is achieved through the combined effect of plasmonic electrons from the deposited metal, hole scavenger solvent in the solution, and photoelectrons excited by photons. With the coexistence of laser, plasmonic metal, and hole scavenger solvent, the local structure of the semiconductor of the first substrate 110 beneath the deposited metal transforms into a metallic phase (i.e., the local structure 112 in FIG. 1B and FIG. 1C), facilitating ohmic contact.

Thereafter, as shown in FIG. 2D, a further stage is undertaken to obtain one or more electrodes with the desired shape. Briefly, by controlling the relative movement of the light source 160 to the target sample (e.g., the reagent applied to the first substrate 110), continuous deposition of metal result in one or more electrodes. Further, the light source 160 can extend to an area without semiconductor of the first substrate 110) for the convenience of measurement. In one embodiment, the laser writing process is repeated, and thorough cleaning of the sample is applied to finalize the FET configuration. In the stage of FIG. 2D, the local structure 112 for the phase transition layer is formed as well; it should be noted that the dimension/profile/shape of the local structure 112 for the phase transition layer depicted in FIG. 2D is illustrative.

For example, the light source moves, thus causing its focus to move as well, so as to make the mechanically rigid conductive deposition 130 formed as a conductive pattern on the first substrate 110, in which a distribution area of the conductive pattern depends on a moving zone of the focus of the light source 120 (e.g., a zone from the irradiation by the light beam 162A to the irradiation by the light beam 162B).

For example, the light source moves from the first substrate 110 to the second substrate 120 along a moving path (e.g., a path from the light beam 162A to the light beam 162C), thus causing its focus to move along the same path as well, so as to form the mechanically rigid conductive deposition 130 along the moving path, such that the conductive pattern of the mechanically rigid conductive deposition 130 extends from the first substrate 110 to the second substrate 120.

In one embodiment, after forming a deposition, the method can be repeated for thicker or denser deposition (e.g., the mechanically rigid conductive deposition 130); or the method can be repeated for different material deposition by changing the first solution 150 containing metalate or metal ions or the first suspension 152 containing the nanoparticles or light sensitive reducing agent.

In various embodiments, the light source 160 is a laser, particularly a continuous wave laser or a pulsed laser, preferably in the visible range and preferably with a wavelength of 532 nm. In various embodiments, the light source 160 is focused by means of a lens, preferably an air objective lens, an oil objective lens, or a water immersion objective lens. In various embodiments, the light from the light source 160 can be guided to the reagent via free space, and/or via at least one photonic waveguide, and/or via at least one optical fiber, and/or via evanescent coupling. In the process as aforementioned, the power of the light or the laser is kept at a low level, such as 400 mW at maximum for any substrate. The power depends on the numerical aperture value of the applied objective. In contrast, common laser writing methods require a high-power ultrafast laser.

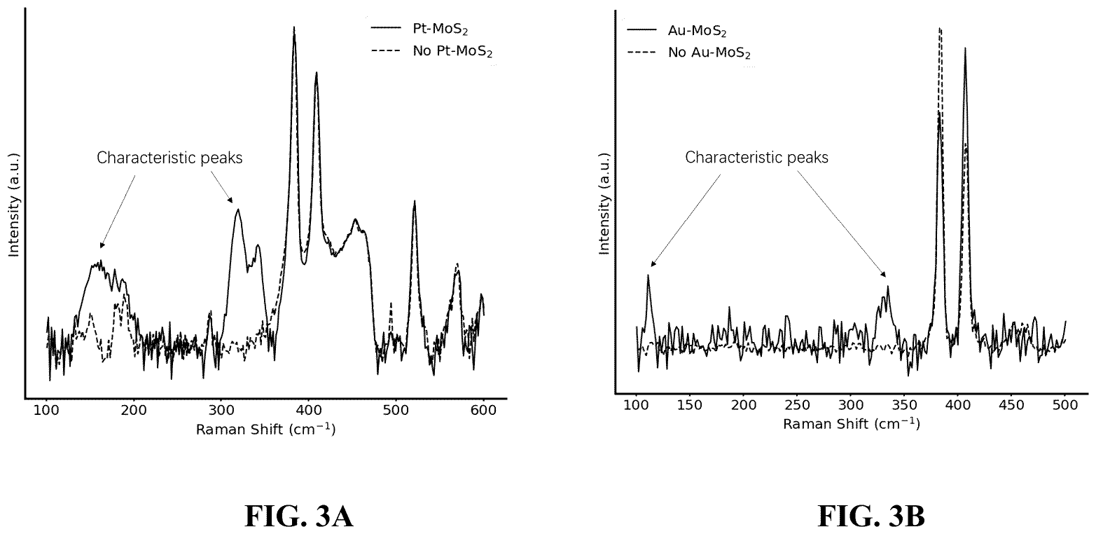

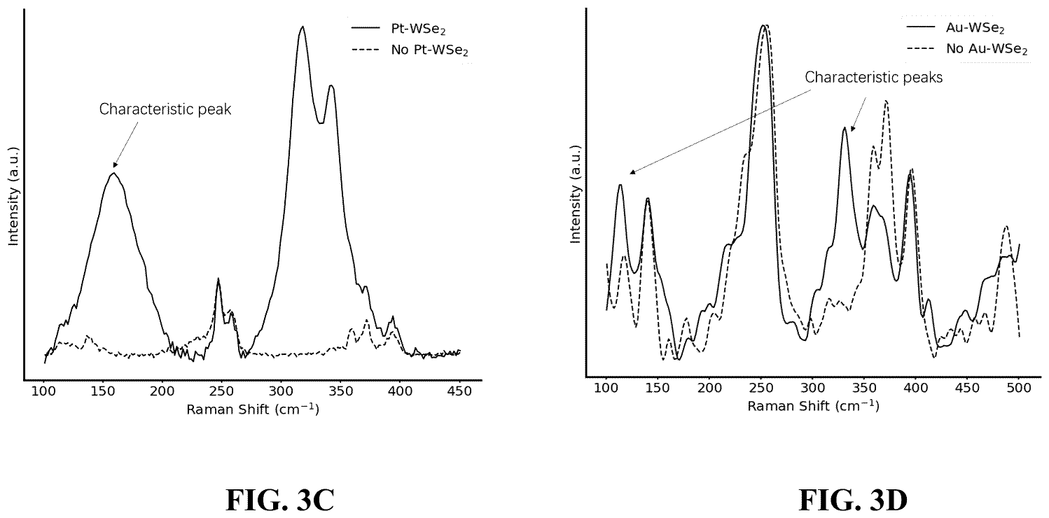

FIG. 3A, FIG. 3B, FIG. 3C, and FIG. 3D demonstrate the Raman spectrum analysis of different precious metal deposition on different TMDs according to some embodiments of the present invention. These Raman spectrums are the strong proof for the existence of phase transition of TMDs in situ. FIG. 3A is made for Pt on MoS₂ and FIG. 3B is made for Au on MoS₂; they show that the lattice of MoS₂ beneath the deposited material is transformed to metallic phase, while the other areas of MoS₂ remain semiconductive as channel. FIG. 3C is made for Pt on WSe₂ and FIG. 3D is made for Au on WSe₂; they also show the same metallic phase transition of deposited area, remaining channel area unchanged.

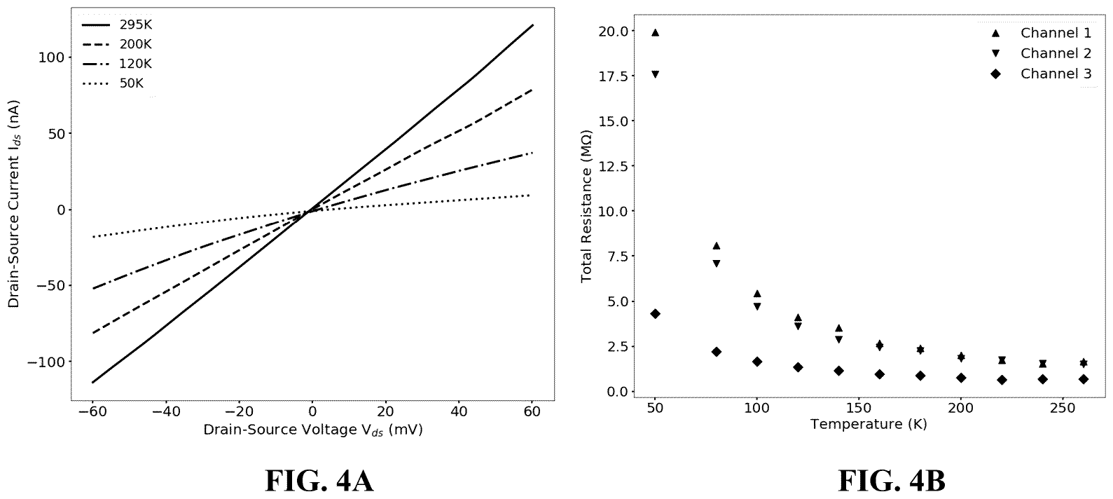

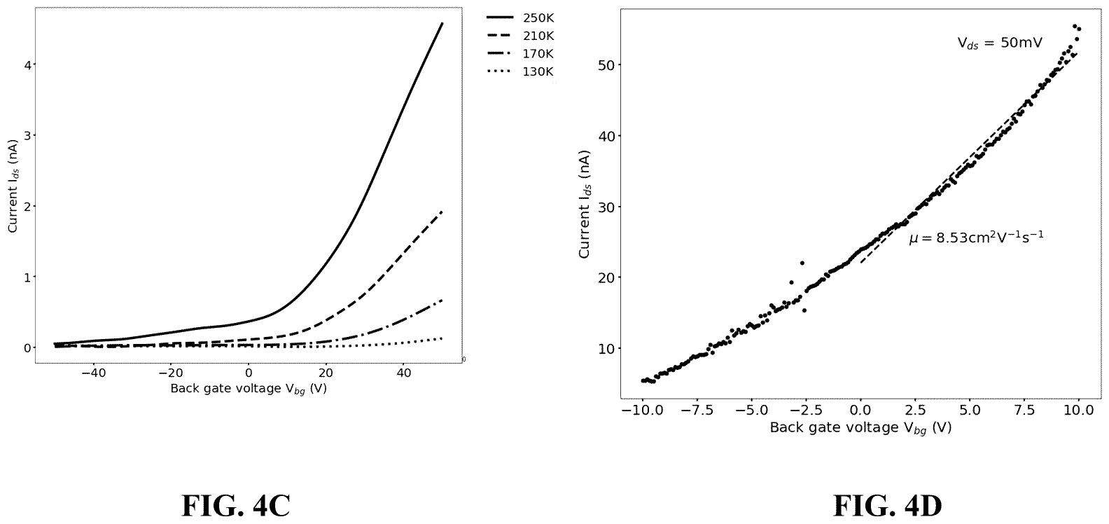

To verify the ohmic contact on M-S interface, testing for electrical characterization of Pt-MoS₂ devices at different temperature is performed. FIG. 4A, FIG. 4B, FIG. 4C, FIG. 4D collectively provide electrical measurement of a FET device manufactured using the solution according to some embodiments of the present invention. The sample for the FET device is MoS₂-based with Pt electrodes, which contains multi-channel on the same piece of TMDs.

As shown in FIG. 4A and FIG. 4B, by applying a drain-source bias voltage (Vds) to different pairs of platinum electrodes on the same sample, the total resistance of the metal-semiconductor (M-S) contact and channel transportation is measured. The total resistance refers to the sum of channel resistance and contact resistance. In FIG. 4A, the linear relationship of measured current between source and drain to applied voltage provides strong evidence of ohmic contact. The measured total resistance at room temperature is about 2 MΩ. In FIG. 4B, the illustration shows the temperature dependence of total resistance by different channels on the same sample, exhibiting a negative exponential correlation, which conforms to the electrical properties of the channel material. As such, FIG. 4A directly proof the ohmic contact of M-S interface, as the linear relationship of applied drain-source bias voltage and measured drain-source current; FIG. 4B shows the decreasing of total resistance as the temperature decreased, the same as the behavior of the semiconductor, which proof the ohmic contact from the side.

Furthermore, a MoS₂ FET with a scale of 15 μm is fabricated to fully demonstrate the potential and further applications of the present invention. The FET output current at the same drain-source voltage (Vds) is measured under different back-gate voltages, and excellent current saturation is observed. FIG. 4C shows the transfer characteristics of the FET device under different temperatures, where N-type channel behavior is observed. Moreover, FIG. 4D shows the mobility of the FET device, which is reasonable and ready for use. The mobility of the fabricated FET device is deduced to be about 8.5 cm²V⁻¹s⁻¹, which is already at a usable level.

Furthermore, by the solution provided by the present invention, it can deposit solid metallic structure with strong adhesion to the substrate that they remain intact after being ultrasound for more than 30 minutes in different solvents, including acetone, iso-propanol or ethanol. In one embodiment, the solution provided by the present invention can be combined with optical characterization of semiconductor samples, which allows sample selection, device fabrication and optical quality inspection within same setup. In one embodiment, the solution provided by the present invention can be used for making electronics, fabricating flexible devices and/or quantum devices, and/or photonic structures, and/or electrodes for testing electronic properties of 2D-material, especially in a way to print the circuit with a printer.

Based on the above, various embodiments of the present invention also provide more structural configurations.

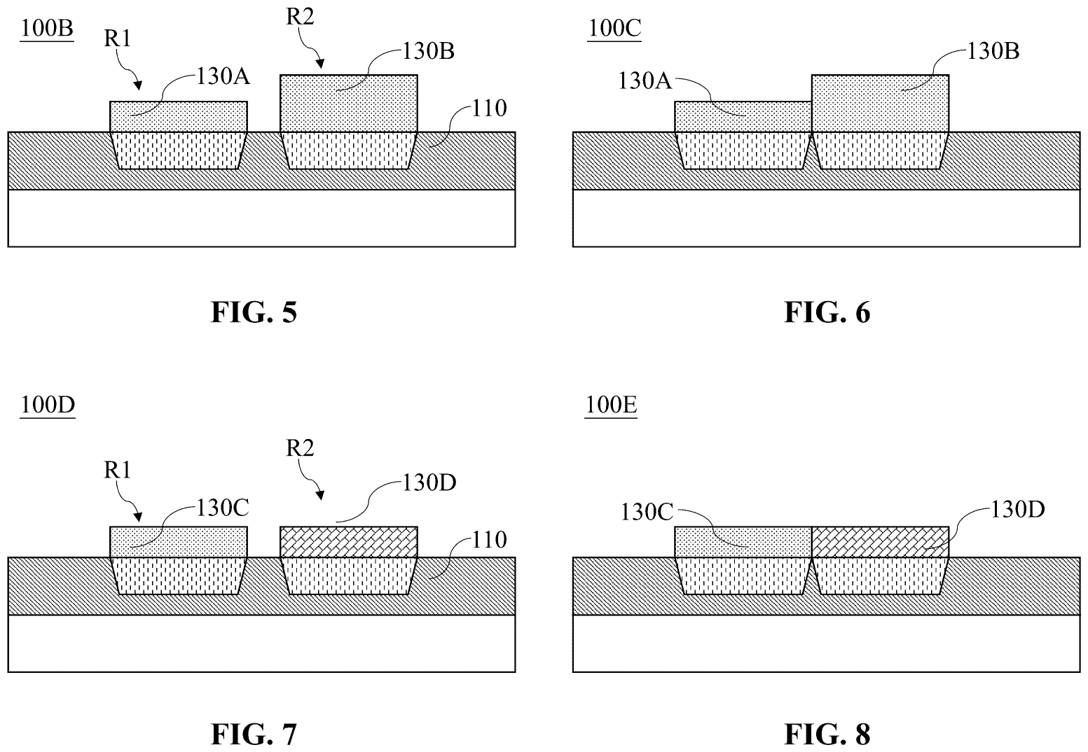

FIG. 5 is a vertical cross-sectional view of a semiconductor device 100B according to some embodiments of the present disclosure. The configuration of the semiconductor device 100B is similar with that of the semiconductor device 100A, except the semiconductor device 100B further includes electrodes with different thicknesses formed by mechanically rigid conductive deposition 130A, 130B. The mechanically rigid conductive deposition 130A and the mechanically rigid conductive deposition 130B are formed within different regions (e.g., the first region R1 and the second region R2) of the first substrate 110 and have different thicknesses. The mechanically rigid conductive deposition 130A and the mechanically rigid conductive deposition 130B may have the same composition.

During the process, the solution and the suspension are mixed on the first substrate 110 to form a reagent again; thereafter, the light beam is focused onto the reagent kept on a region different than the first region RI within the first substrate 110, so as to form an additional conductive deposition 130B in contact with the first substrate 110. Moreover, the mechanically rigid conductive deposition 130B is formed by repeating the steps shown in the stages of FIG. 2A, FIG. 2B, and FIG. 2C multiple times (i.e., more times than the formation for the mechanically rigid conductive deposition 130A).

FIG. 6 is a vertical cross-sectional view of a semiconductor device 100C according to some embodiments of the present disclosure. The configuration of the semiconductor device 100C is similar with that of the semiconductor device 100B, except the semiconductor device 100C includes electrodes with different thicknesses formed by the mechanically rigid conductive deposition 130A, 130B in contact with each other. The mechanically rigid conductive deposition 130A, 130B in contact with each other can provide a modulating effect on resistance for electrodes.

FIG. 7 is a vertical cross-sectional view of a semiconductor device 100D according to some embodiments of the present disclosure. The configuration of the semiconductor device 100D is similar with that of the semiconductor device 100A, except the semiconductor device 100D further includes electrodes formed by mechanically rigid conductive deposition 130C, 130D containing different compositions. In one embodiment, the mechanically rigid conductive deposition 130C and the mechanically rigid conductive deposition 130D have different metal elements. For example, the mechanically rigid conductive deposition 130D has a metal element absent in the mechanically rigid conductive deposition 130C.

The mechanically rigid conductive deposition 130C can be formed by the approach as afore-described. During the process, a second solution is prepared and is mixed with a suspension to form a second reagent on the first substrate 110, which contains different elements than that of the first reagent 154 in FIG. 2B (e.g., the second reagent includes an element or compound absent in the first reagent); thereafter, the light beam is focused onto the second reagent kept on a region different than the first region RI within the first substrate 110, so as to form an additional conductive deposition 130D in contact with the first substrate 110. As such, electrodes of the mechanically rigid conductive deposition 130C, 130D may have different characteristics, providing a modulating effect on resistance thereof.

FIG. 8 is a vertical cross-sectional view of a semiconductor device 100E according to some embodiments of the present disclosure. The configuration of the semiconductor device 100E is similar with that of the semiconductor device 100D, except the semiconductor device 100E includes electrodes formed by the mechanically rigid conductive deposition 130C, 130D in contact with each other.

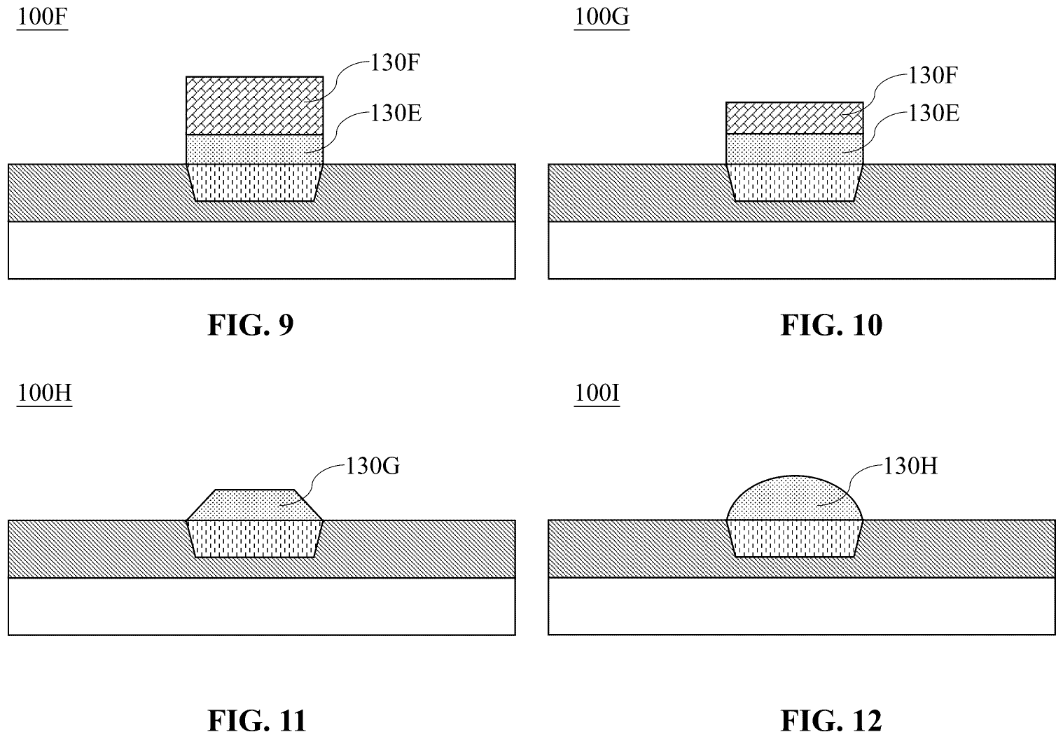

FIG. 9 is a vertical cross-sectional view of a semiconductor device 100F according to some embodiments of the present disclosure. The configuration of the semiconductor device 100F is similar with that of the semiconductor device 100A, except the semiconductor device 100F further includes an electrode formed by mechanically rigid conductive deposition 130F disposed above the mechanically rigid conductive deposition 130E. Specifically, the mechanically rigid conductive deposition 130F has a composition different than that of the mechanically rigid conductive deposition 130E and is formed in contact with a top surface of the mechanically rigid conductive deposition 130E. In one embodiment, the mechanically rigid conductive deposition 130E and the mechanically rigid conductive deposition 130F have different thicknesses. For example, the mechanically rigid conductive deposition 130F is thicker than the mechanically rigid conductive deposition 130E. In one embodiment, the formation of the mechanically rigid conductive deposition 130F is controlled such that the mechanically rigid conductive deposition 130E and the mechanically rigid conductive deposition 130F have the same width.

The mechanically rigid conductive deposition 130E can be formed by the approach as afore-described. During the process, a second solution is prepared and is mixed with a suspension to form a second reagent on the mechanically rigid conductive deposition 130E (e.g., the second reagent includes an element or compound absent in the first reagent); thereafter, the light beam is focused onto the second reagent kept on mechanically rigid conductive deposition 130E, so as to form an additional conductive deposition 130F in contact with the mechanically rigid conductive deposition 130E. As such, electrodes of the mechanically rigid conductive deposition 130E, 130F may provide a desired modulating effect on resistance thereof.

FIG. 10 is a vertical cross-sectional view of a semiconductor device 100G according to some embodiments of the present disclosure. The configuration of the semiconductor device 100G is similar with that of the semiconductor device 100F, except the semiconductor device 100G includes electrodes formed by the mechanically rigid conductive deposition 130C, 130D having the same thickness.

FIG. 11 is a vertical cross-sectional view of a semiconductor device 100H according to some embodiments of the present disclosure. The configuration of the semiconductor device 100H is similar with that of the semiconductor device 100A, except the semiconductor device 100F further includes an electrode formed by mechanically rigid conductive deposition 130G with an inverted trapezoidal shape. FIG. 12 is a vertical cross-sectional view of a semiconductor device 100I according to some embodiments of the present disclosure. The configuration of the semiconductor device 100I is similar with that of the semiconductor device 100A, except the semiconductor device 100I further includes an electrode formed by mechanically rigid conductive deposition 130H with a curved surface. For mechanically rigid conductive depositions of different shapes, controlling the movement trajectory of the laser source when forming their conductive patterns via the laser beam can generate the desired different shapes. In other words, the movement trajectory of the laser beam can determine the profile of the electrodes.

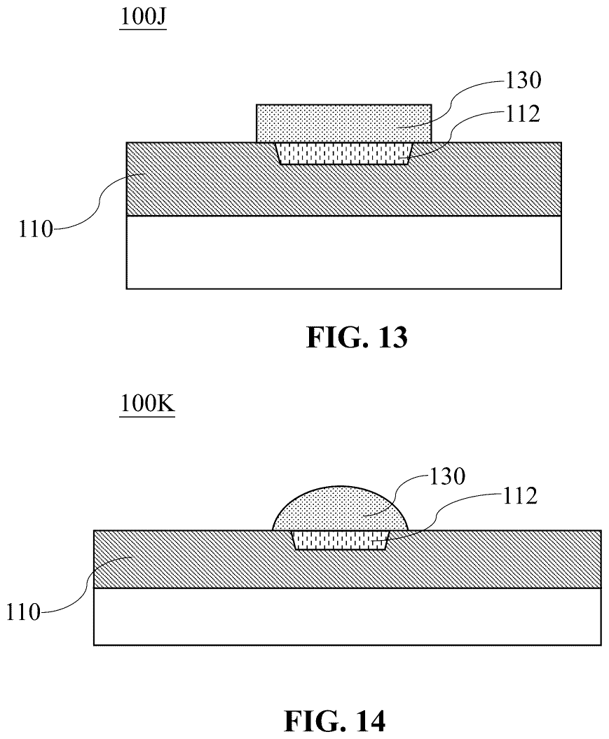

FIG. 13 is a vertical cross-sectional view of a semiconductor device 100J according to some embodiments of the present disclosure; and FIG. 14 is a vertical cross-sectional view of a semiconductor device 100K according to some embodiments of the present disclosure. The configurations of the semiconductor devices 100I and 100K are similar with the configurations as afore-described, except the local structure 112 for the phase transition layer in the first substrate 110 is smaller than the mechanically rigid conductive deposition 130 (e.g., narrower than the mechanically rigid conductive deposition 130), which means that portions of the first substrate 110 beneath the mechanically rigid conductive deposition 130 is transited to metallic area as the illustrated local structure 112 (i.e., at least one portion of the first substrate 110 beneath the mechanically rigid conductive deposition 130 remains intrinsic still).

As discussed above, in the present disclosure, the conductive material deposition on the surface of semiconductor with ohmic contact by phase transition in situ is achieved, with advantages as follows:
(1) Local phase transition could be achieved without any change in the semiconductor material of the channel part.
(2) This method allows for direct electrical measurement on the semiconductor.
(3) The contact resistance of the M-S surface is equivalently small.
(4) This method can use precious metals as electrodes to reduce electrode resistance.
(5) This method can be deployed in a trivial environment at room temperature, without extreme conditions.
(6) This method requires a minimum cost of energy and solution.
(7) This method is ready to go and could manufacture a testing sample in minutes.
(8) This method allows for sample selection, electrode deposition, and optical inspection processes integrated into a single setup.
(9) This method allows surface phase transition, which would not change the structure of the semiconductor beneath the surface.
(10) This method can achieve ohmic contact without any damage to the semiconductor sample.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A method for a photon induced conductive material deposition on a substrate, comprising:
preparing a first solution comprising metalate, metal ions, or combinations thereof;
preparing a first suspension comprising nanoparticles, a light sensitive reducing agent, an electron providing solvent, or combinations thereof;
mixing the first solution and the first suspension to form a first reagent on a first substrate; and
emitting a light beam provided by a light source and focusing the same onto the first reagent kept on a first region of the first substrate, so as to form a mechanically rigid conductive deposition in contact with the first substrate in a focus point of the light source, wherein the first substrate has a second region exposed to surrounding gas or an air environment.

2. The method according to claim 1, wherein the first substrate comprises MoS₂, MoSe₂, MoTe₂, WSe₂, graphene, a layer with metallic isomers, or combinations thereof, serving as two-dimensional materials to form at least one channel within the first substrate.

3. The method according to claim 2, wherein the mechanically rigid conductive deposition forms an ohmic contact with the first region of the first substrate in situ.

4. The method according to claim 1, further comprising:
moving the focus of the light source to make the mechanically rigid conductive deposition formed as a conductive pattern on the first substrate, wherein a distribution area of the conductive pattern depends on a moving zone of the focus of the light source.

5. The method according to claim 4, wherein the first substrate is positioned over and attached to a second substrate, and the method further comprises:
moving the focus of the light source from the first substrate to the second substrate along a moving path, so as to form the mechanically rigid conductive deposition along the moving path, such that the conductive pattern of the mechanically rigid conductive deposition extends from the first substrate to the second substrate.

6. The method according to claim 5, wherein the second substrate comprises glass, quartz, sapphire, indium tin oxide, diamond, Si, SiC, oxidized silicon, combinations thereof.

7. The method according to claim 1, wherein the first solution comprises gold(III) chloride hydrochloride (HAuCl₄), chloroplatinic acid (H₂PtCl₆), silver nitrate (AgNO₃), or combinations thereof.

8. The method according to claim 1, wherein the electron providing solvent comprises water, ethanol, propanol, isopropanol, acetone, methanol, or combinations thereof.

9. The method according to claim 1, wherein the light sensitive reducing agent comprises reduced graphene oxide, quantum dots, carbon ink particles, or combinations thereof.

10. The method according to claim 1, wherein the first substrate is a semiconductor, and forming the mechanically rigid conductive deposition result in creating phase transition at a semiconductor surface of the first region of the first substrate locally without changing at least one property of the semiconductor in the second region of the first substrate.

11. The method according to claim 1, wherein the mechanically rigid conductive deposition is a solid and rigid composite pattern made of pure metal, solid metal salt, metal oxide, or combinations thereof.

12. The method according to claim 1, further comprising;
mixing the first solution and the first suspension to form a second reagent on the first substrate after the formation of the mechanically rigid conductive deposition; and
focusing the light beam provided by the light source onto the second reagent kept on a third region of the first substrate, so as to form an additional conductive deposition in contact with the third region of the first substrate.

13. The method according to claim 1, further comprising;
mixing the first solution and the first suspension to form a second reagent on the mechanically rigid conductive deposition; and
focusing the light beam provided by the light source onto the second reagent kept on the mechanically rigid conductive deposition, so as to form an additional conductive deposition in contact with the mechanically rigid conductive deposition.

14. The method according to claim 1, further comprising;
forming a second reagent on the first substrate after the formation of the mechanically rigid conductive deposition, wherein the second reagent comprises an element or compound absent in the first reagent; and
focusing the light beam provided by the light source onto the second reagent kept on a third region of the first substrate, so as to form an additional conductive deposition in contact with the third region of the first substrate.

15. A semiconductor device using a photon induced conductive material deposition, comprising:
a first substrate having a first region and a second region adjacent to the first region, wherein the first substrate comprises MoS₂, MoSe₂, MoTe₂, WSe₂, graphene, a layer with metallic isomers, or combinations thereof, serving as two-dimensional materials to form at least one channel within the first substrate;
a mechanically rigid conductive deposition formed as a conductive pattern disposed above the first region of the first substrate, wherein the mechanically rigid conductive deposition forms an ohmic contact with the first region of the first substrate and is a solid and rigid composite pattern made of pure metal, solid metal salt, metal oxide, or combinations thereof; and
a second substrate attached to the first substrate, wherein the mechanically rigid conductive deposition is above the first substrate and the second substrate and extends from the first region of the first substrate to the second substrate.

16. The semiconductor device according to claim 15, wherein the second substrate comprises glass, quartz, sapphire, indium tin oxide, diamond, Si, SiC, oxidized silicon, combinations thereof.

17. The semiconductor device according to claim 16, further comprising:
an additional conductive deposition formed as a conductive pattern disposed above the second region of the first substrate, wherein the additional conductive deposition forms an ohmic contact with the second region of the first substrate and is a solid and rigid composite pattern made of pure metal, solid metal salt, metal oxide, or combinations thereof.

18. The semiconductor device according to claim 17, wherein the mechanically rigid conductive deposition and the additional conductive deposition have different metal elements.

19. The semiconductor device according to claim 17, wherein the mechanically rigid conductive deposition and the additional conductive deposition have different thicknesses.

20. The semiconductor device according to claim 17, wherein the additional conductive deposition has a metal element absent in the mechanically rigid conductive deposition.
